(19) United States
(12) Patent Application Publication
(10) Pub. No.: US 2017/0278869 A1
(43) Pub. Date: Sep. 28, 2017

(54) METHOD FOR MANUFACTURING SEMICONDUCTOR DEVICE

(71) Applicant: Japan Display Inc., Minato-ku (JP)

(72) Inventors: Masato Hiramatsu, Minato-ku (JP); Hiroki Ohara, Minato-ku (JP)

(73) Assignee: Japan Display Inc., Minato-ku (JP)

(21) Appl. No.: 15/465,106

(22) Filed: Mar. 21, 2017

(30) Foreign Application Priority Data
Mar. 23, 2016 (JP) 2016-058704

(51) Int. Cl. H01L 27/12; H01L 29/786

(52) U.S. Cl. CPC H01L 27/127; H01L 27/1222; H01L 27/1225; H01L 27/124; H01L 27/1255; H01L 29/78675; H01L 29/7869; H01L 29/78696; H01L 29/78621; H01L 27/3262

(57) ABSTRACT

A first semiconductor layer is formed on an insulating surface. A first insulating layer for covering an upper side of the first semiconductor layer is formed. On the first insulating layer, a second semiconductor layer is formed. A second insulating layer for covering an upper side of the second semiconductor layer is formed. A first contact hole extending through the first and second insulating layers to reach the first semiconductor, and a second contact hole extending through the second insulating layer to reach the second semiconductor layer but not reaching the first insulating layer are opened. After the step of forming the second insulating layer before the step of opening the first and second contact holes, laser or heat annealing process is executed.

### CROSS-REFERENCE TO RELATED APPLICATION

The present application claims priority from Japanese application JP2016-058704 filed on Mar. 23, 2016, the content of which is hereby incorporated by reference into this application.

### BACKGROUND OF THE INVENTION

1. Field of the Invention

The present invention relates to a method for manufacturing a semiconductor device.

2. Description of the Related Art

In a semiconductor device having a plurality of kinds of transistors, semiconductor layers having different properties depending on the kind of a transistor may coexist. In a process for manufacturing a device having a plurality of kinds of semiconductors, there may be a case in which an order in forming semiconductors on an insulating flat surface of the device may be subjected to restriction due to difference in condition (for example, temperature condition) for forming various semiconductors. For example, when the temperature in forming a first semiconductor layer is higher than that in forming a second semiconductor layer, it is necessary to first form the first semiconductor layer on an insulating flat surface and then form the second semiconductor layer. Accordingly, the second semiconductor layer formed with such restriction is positioned higher than the first semiconductor layer relative to the insulating flat surface. In the specifications of U.S. Patent Application Publications 2010/0182223 and 2015/0055051, a polysilicon layer, or a semiconductor layer, and an oxide semiconductor layer are formed, in which the oxide semiconductor layer is formed on the polysilicon layer.

### SUMMARY OF THE INVENTION

In a process for manufacturing a semiconductor device, for example, first and second semiconductor layers with different conditions for formation are formed, and an insulating layer is then formed covering the first and second semiconductor layers. Thereafter, in order to form electrode layers for electric connection to the first and second respective semiconductor layers, a contact hole reaching the first semiconductor layer and a second contact hole reaching the second semiconductor layer are opened in the insulating layer. Specifically, the first and second contact holes may be formed by means of dry etching using fluorine-based gas (for example, etching gas).

Note here that, as described above, there may be a case in which the second semiconductor layer is formed on the first semiconductor layer due to difference in the temperature condition, etc. In the above, in the case where a process for opening the first contact hole and a process for opening the second contact hole begin at the same time, the first contact hole is yet to reach the first semiconductor layer at a time when the second contact hole has reached the second semiconductor layer. Therefore, the second semiconductor layer remains exposed to the etching gas via the second contact hole during a period from when the second contact hole has reached the second semiconductor layer to when the first contact hole reaches the first semiconductor layer.

With the second semiconductor layer exposed to the etching gas, as described above, an exposed part of the second semiconductor layer may be etched, and reliable contact to the second semiconductor layer cannot be ensured. In such a case, there is a possibility that an electrode layer to be formed in the second contact hole at a subsequent step is not able to be electrically connected to the second semiconductor layer.

One object of the present invention is to provide a method for manufacturing a semiconductor device capable of improving tolerance of a second semiconductor layer to an etching gas before formation of a second contact hole, and to ensure reliable contact to the second semiconductor layer.

A method for manufacturing a semiconductor device according to one aspect of the present invention is a method for manufacturing a semiconductor device, including steps of forming a first semiconductor layer on an insulating surface; forming a first insulating layer covering an upper side of the first semiconductor layer; forming a second semiconductor layer on the first insulating layer; forming a second insulating layer covering an upper side of the second semiconductor layer; opening a first contact hole extending through the first insulating layer and the second insulating layer to reach the first semiconductor layer, and a second contact hole extending through the second insulating layer to reach the second semiconductor layer but not reaching the first insulating layer; and executing annealing process using laser or heat. In the above, the annealing process is executed after the step of forming the second insulating layer before the step of opening the first contact hole and the second contact hole. With the above, it is possible to improve tolerance of the second semiconductor layer to an etching gas before formation of the second contact hole to ensure reliable contact to the second semiconductor layer.

### BRIEF DESCRIPTION OF THE DRAWINGS

FIG. 1 is a schematic cross sectional showing a part of a semiconductor device according to an embodiment;

FIG. 2A shows one example of a method for manufacturing a semiconductor device 1;

FIG. 2B shows one example of a method for manufacturing a semiconductor device 1;

FIG. 2C shows one example of a method for manufacturing a semiconductor device 1;

FIG. 2D shows one example of a method for manufacturing a semiconductor device 1;

FIG. 2E shows one example of a method for manufacturing a semiconductor device 1;

FIG. 3 shows another example of a method for manufacturing a semiconductor device 1;

FIG. 4 is a schematic cross sectional view showing a part of a semiconductor device according to a first modified example;

FIG. 5 is a schematic cross sectional view showing a part of a semiconductor device according to a second modified example;

FIG. 6 is a schematic plan view of a display device according to a third modified example;

FIG. 7 is a cross sectional view showing a part of a display device according to the third modified example; and

FIG. 8 is a cross sectional view showing a part of a display device according to the third modified example.

### DETAILED DESCRIPTION OF THE INVENTION

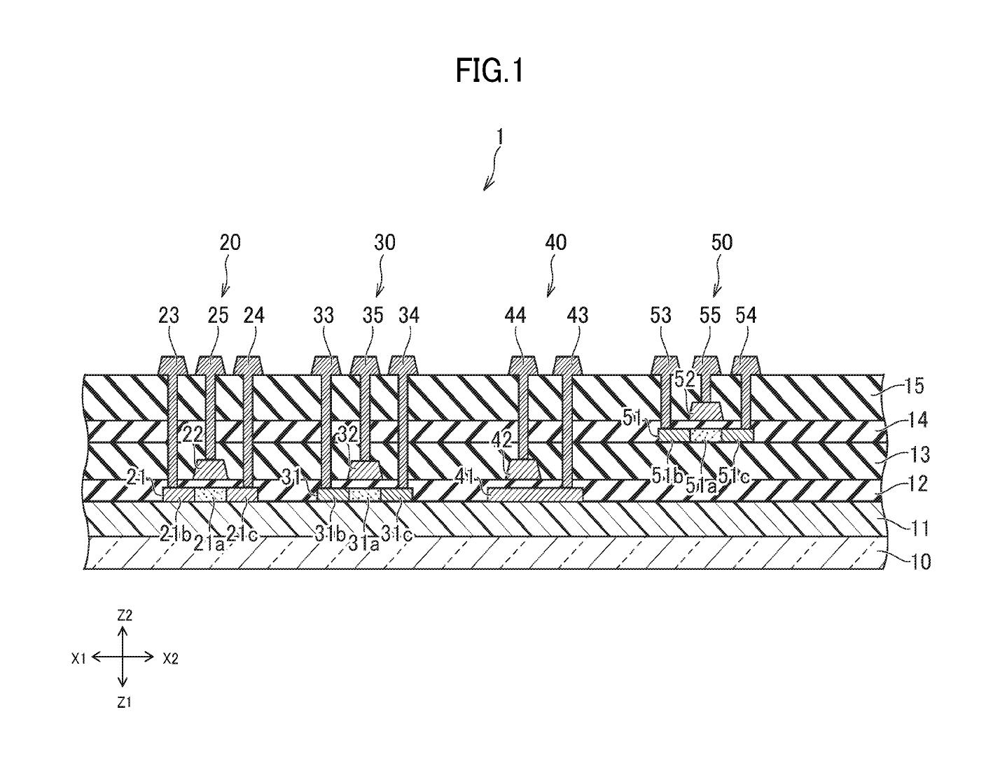

In the following, an embodiment for rendering the present invention into practice (an embodiment) will be described referring to FIGS. 1 to 8. Note that the disclosure of this specification concerns one mere example of the present invention, and any modification holding the gist of the present invention and readily conceivable by a person skilled in the art is included in the scope of the present invention. Also, the width, thickness, and shape shown in the respective drawings are shown schematically, and do not limit interpretation of the present invention. In the description below, positional relationship of the respective structures will be described based on the coordinates of the X axis (the X1 direction, and the X2 direction), the Y axis (the Y1 direction, the Y2 direction), and the Z axis (the Z1 direction, the Z2 direction).

In this embodiment, in expressing an aspect in which a structure is placed “on the top of” another structure, a simple description of “on” includes both of a case in which one structure is placed directly on another structure such that the structures are in contact with each other and a case in which one structure is placed via a third structure above another structure, unless otherwise stated.

### 1. Outline of Semiconductor Device

FIG. 1 is a schematic cross sectional view showing a part of a semiconductor device 1 according to this embodiment. As shown in FIG. 1, a plurality of kinds of transistors are formed in one substrate 10 of the semiconductor device 1. More specifically, an N-type transistor 20, a P-type transistor 30, a capacitor portion 40, and an oxide transistor 50 are integrally formed in the semiconductor device 1. In the semiconductor device 1, it is possible that the N-type transistor 20 and the P-type transistor 30 can be combined to thereby constitute a CMOS circuit.

The N-type transistor 20, the P-type transistor 30, and the capacitor portion 40 contain first semiconductor layers 21, 31, 41, respectively. Each of the first semiconductor layers 21, 31, may contain any of single-crystalline silicon, poly-crystalline silicon, and microcrystal silicon. In this embodiment, each of the first semiconductor layers 21, 31, 41 is made from low temperature polysilicon (LIPS).

The first semiconductor layer 21 constituting the N-type transistor 20 includes a channel region 21a that functions as a channel, and a source region 21b and a drain region 21c, or regions for electric connection to respective electrode layers 23, 24 to be described later. In the source region 21b and the drain region 21c, phosphorus (P) ions or arsenic (As) ions, etc., are injected, so that the first semiconductor layer 21 functions as an N-type semiconductor. The channel region 21a overlaps a first gate electrode layer 22 to be described later in a vertical direction (the Z axial direction), and becomes an on state with potential difference given between the first gate electrode layer 22 and the source region 21b, so that electrons, or carriers, flow in the channel region 21a.

In the first semiconductor layer 31 constituting the P-type transistor 30 as well, a channel region 31a, a source region 31b, and a drain region 31c are formed. In the source region 31b and the drain region 31c, boron ions (B) etc., are injected, and the first semiconductor layer 31 functions as a P-type semiconductor. The channel region 31a overlaps a first gate electrode layer 32 to be described later in the vertical direction, and becomes an on state with potential difference given to the first gate electrode layer 32 and the source region 31b, so that holes, or carriers, flow in the channel region 21a.

In the capacitor portion 40, the first semiconductor layer 41 for forming a capacitor between itself and a capacitor electrode layer 42 to be described later is formed. Phosphorus ions, etc., are injected into the entire first semiconductor layer 41, so that the first semiconductor layer 41 as a whole has lower resistance. With the above, the first semiconductor layer 41 functions as a capacitor electrode.

Each of the first semiconductor layers 21, 31, 41 is formed on the upper side (the side of the Z2 direction) of an undercoat layer 11 formed on the substrate 10. The substrate 10 may be made of an insulating substrate, including polyimide, resin, acryl, PET, etc., for example. The undercoat layer 11 is available to prevent invasion of oxygen and water into the first semiconductor layers 21, 31, 41, and may be made from insulating material, such as a silicon oxide film (SiOx), a silicon nitride film (SiNy), etc., for example, or by laminating layers of these inorganic materials.

The upper sides of the first semiconductor layers 21, 31, are covered by a first insulating layer 12. The first insulating layer 12 functions as a gate insulating film in the N-type transistor 20 and the P-type transistor 30, and also as a dielectric of the capacitor portion 40. The first insulating layer 12 may be made from inorganic insulating material, such as a silicon oxide film, etc., for example.

The N-type transistor 20 and the P-type transistor 30 respectively include first gate electrode layers 22, 32. Each of the first gate electrode layers 22, 32 is made from predetermined electrically conducting material, and specifically, made from titanium (Ti) or aluminum (Al), for example, or by laminating layers of these materials. The capacitor portion 40 includes a capacitor electrode layer 42 made from predetermined electrically conducting material.

In this embodiment, each of the N-type transistor 20 and the P-type transistor 30 is a top gate type. That is, the first gate electrode layers 22, 32 are formed on the first insulating layer 12. The capacitor electrode layer 42 as well is formed on the first insulating layer 12. Specifically, the first gate electrode layer 22 covers at least a part of the first semiconductor layer 21. More specifically, the first gate electrode layer 22 overlaps the channel region 21a of the first semiconductor layer 21 in the vertical direction. Similarly, the first gate electrode layer 32 covers the channel region 31a of the first semiconductor layer 31, and the capacitor electrode layer 42 covers at least a part of the first semiconductor layer 41.

The upper sides of the first gate electrode layers 22, 32 and the capacitor electrode layer 42 are covered by a first upper insulating layer 13. The first upper insulating layer 13 may be made of an inorganic insulating layer, such as a silicon nitride film, etc., or by laminating an inorganic insulating layer and an organic insulating layer, such as acryl, etc., (for example, a planarization layer having a flat upper surface).

The oxide transistor 50 includes a second semiconductor layer 51. The second semiconductor layer 51 is a semiconductor layer made from material different in property from the first semiconductor layers 21, 31, 41, and has a condition for formation in the semiconductor device 1 different from that of the first semiconductor layers 21, 31, 41. Specifically, the temperature condition for the second semiconductor layer 51 is different from that of the first semiconductor layers 21, 31, 41. More specifically, the temperature condition (the first temperature condition) of the first semiconductor layers 21, 31, 41 is higher than that (the second temperature condition) of the second semiconductor layer 51. For example, assuming that the first temperature condition is within the temperature range between T1L and T1H ° C. (T1L<T1H), the second temperature condition is within the temperature range between T2L and T2H ° C. (T2L<T2H and T2H<T1H). Note that when the second semiconductor layer 51 is placed at such a temperature that satisfies the first temperature condition, there is a possibility that the second semiconductor layer 51 is deteriorated.

The second semiconductor layer 51 may include an oxide semiconductor layer, for example. As an off current of a transistor made of an oxide semiconductor layer is lower than that of a transistor made of a low temperature polysilicon layer employed as the first semiconductor layers 21, 31, 41, for example, inclusion of an oxide semiconductor layer in the second semiconductor layer 51 can contribute to reduction of power consumption of the semiconductor device 1. A representative example of an oxide semiconductor layer includes indium gallium zinc oxide (InGaZnO), indium gallium oxide (InGaO), indium zinc oxide (InZnO), zinc tin oxide (ZnSnO), zinc oxide (ZnO), etc.

Similar to the first semiconductor layers 21, 31, a channel region 51a, a source region 51b, and a drain region 51c are formed in the second semiconductor layer 51. In a transistor made of an oxide semiconductor layer, it is necessary to partially destroy connection between elements in the oxide semiconductor to thereby generate a defect in order to achieve low resistance of the source region 51b and the drain region 51c. In this embodiment, atoms or ions (more specifically, boron (B) ions), that is, impurities, are injected into the source region 51b and the drain region 51c, whereby low resistance of the source region 51b and the drain region 51c is achieved.

Note that the low resistance of the source region 51b and the drain region 51c when an oxide semiconductor is used is achieved not through control of a valence electron in a semiconductor layer by impurity elements (for example, by setting an excessive electron state or an excessive hole state), different from the case where a low temperature polysilicon layer (LIPS) is used. Therefore, impurity for injection is not limited to boron ions, but phosphorus ions, for example, may be injected.

Further, as long as an effect of generating a defect in a film in the source region 51b and the drain region 51c is obtained, any process other than impurity injection may be applied. As one example, a process of laser irradiation, using the second gate electrode layer 52 as a mask, may be executed after formation of the second gate electrode layer 52.

The second semiconductor layer 51 is formed on the first upper insulating layer 13, and the upper side of the second semiconductor layer 51 is covered by a second insulating layer 14. The second insulating layer 14 may be made from inorganic insulating material, such as a silicon nitride film, etc., for example.

The oxide transistor 50 includes the second gate electrode layer 52 made from predetermined electrically conducting material. In this embodiment, the oxide transistor 50 is a top gate type, and the second gate electrode layer 52 is formed on the second insulating layer 14. Specifically, the second gate electrode layer 52 is formed overlapping the channel region 51a of the second semiconductor layer 51 in the vertical direction so as to cover at least a part of the second semiconductor layer 51.

The upper side of the second gate electrode layer 52 is covered by a second upper insulating layer 15. Similar to the first upper insulating layer 13, the second upper insulating layer 15 may be made of an inorganic insulating layer, such as a silicon nitride film, etc., or includes an organic insulating layer (for example, a planarization layer).

In each of the N-type transistor 20, the P-type transistor 30, the capacitor portion 40, and the oxide transistor 50, an electrode made from predetermined electrically conducting material is formed. More specifically, the N-type transistor 20 includes an electrode layer 23 electrically connected to the source region 21b of the first semiconductor layer 21, the electrode layer 24 connected to the drain region 21c, and an electrode layer 25 connected to the first gate electrode layer 22. Similarly, the P-type transistor 30 includes an electrode layer 33 connected to the source region 31b of the first semiconductor layer 31, the electrode layer 34 connected to the drain region 31c, and the electrode layer 35 connected to the first gate electrode layer 32. The capacitor portion 40 includes an electrode layer 43 connected to the first semiconductor layer 41 and an electrode layer 44 connected to the capacitor electrode layer 42. The oxide transistor 50 includes an electrode layer 53 connected to the source region 51b of the second semiconductor layer 51, an electrode layer 54 connected to the drain region 51c, and an electrode layer 55 connected to the second gate electrode layer 52.

Each of the electrode layers may be formed, for example, by laminating respective layers of titanium (Ti) and aluminum (Al), for example. In this embodiment, the respective electrode layers are formed on the second upper insulating layer 15 so as to extend downward to reach various semiconductor layers or a gate electrode. For example, the electrode layer 23 arranged in the N-type transistor 20 extends through the second upper insulating layer 15, the second insulating layer 14, the first upper insulating layer 13, and the first insulating layer 12 to contact the upper surface of the first semiconductor layer 21. The electrode layer 53 arranged in the oxide transistor 50 extends through the second upper insulating layer 15 and the second insulating layer 14 to contact the upper surface of the second semiconductor layer 51.

As described above, the first semiconductor layers 21, 31, 41 and the second semiconductor layer 51 are formed as semiconductor layers different in property in the semiconductor device 1 according to this embodiment. If the second semiconductor layer 51 is placed in such environment that satisfies a condition (for example, a temperature condition) for forming the first semiconductor layers 21, 31, 41 in the semiconductor device 1, there is a possibility that the second semiconductor layer 51 is deteriorated. Therefore, the second semiconductor layer 51 is arranged at a position far from the first semiconductor layers 21, 31, 41 in the vertical direction (the Z axial direction). Also, in the manufacturing process of the semiconductor device 1, contact holes different in length (depth) in the vertical direction are formed in formation of electrodes in contact with the respective first semiconductor layers 21, 31, 41 and second semiconductor layer 51. In the following, a method for manufacturing the semiconductor device 1 according to this embodiment will be described.

### 2. Method for Manufacturing Semiconductor Device

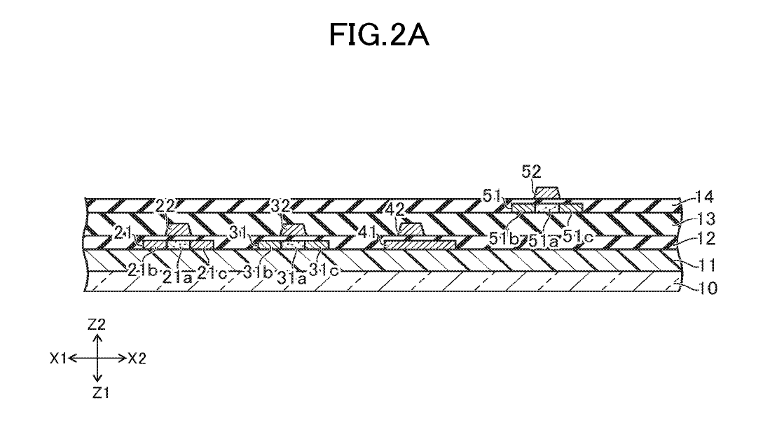

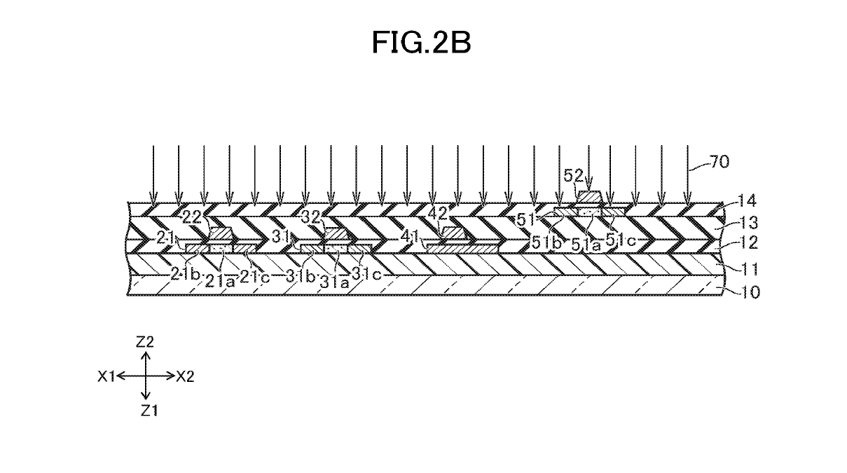

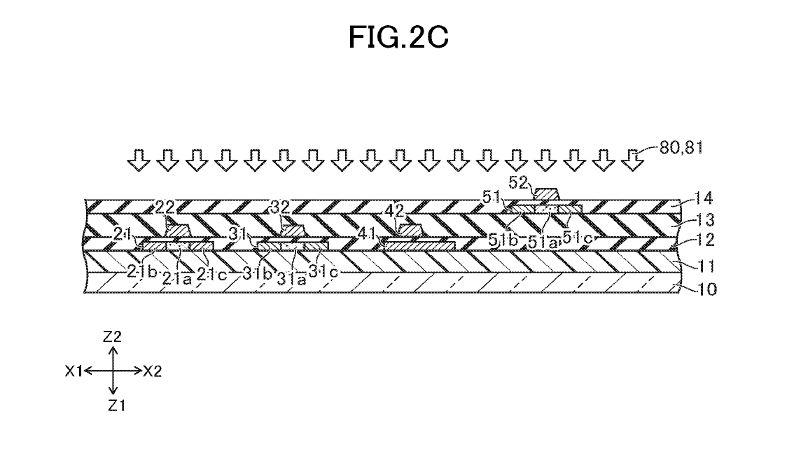

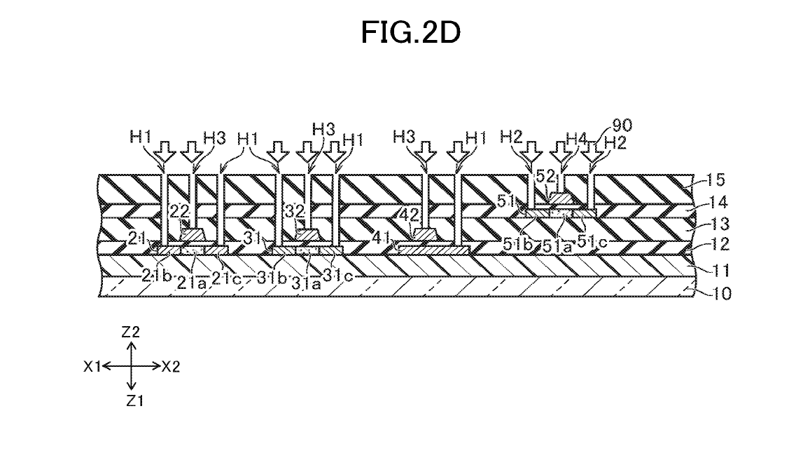

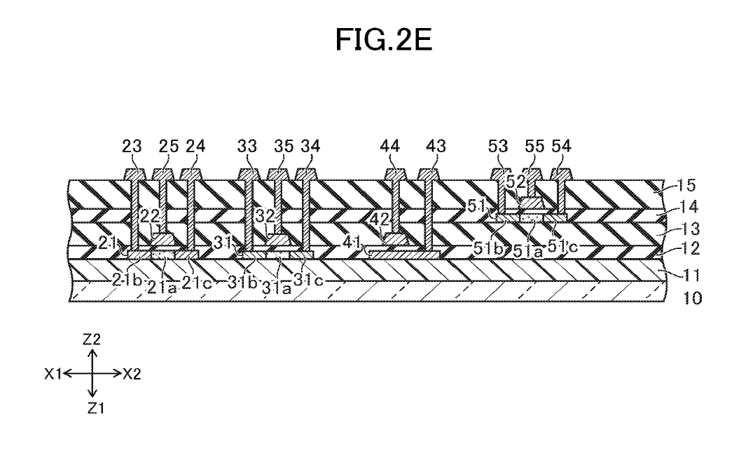

FIGS. 2A to 2E show one example of a method for manufacturing the semiconductor device 1 according to this embodiment. As shown in FIG. 2A, in a manufacturing process of the semiconductor device 1, the first semiconductor layers 21, 31, 41 are formed on a surface of the undercoat layer 11, or an insulating flat surface, and then a first insulating layer 12 made of a silicon oxide film, etc., is formed covering the upper sides of the first semiconductor layers 21, 31, 41. The first semiconductor layers 21, 31, 41 may be made by means of photolithography technique by removing (an etching process) an unnecessary part from a single semiconductor layer (for example, a low temperature polysilicon layer).

As described above, the first semiconductor layers 21, 31, 41 are formed in such a condition (for example, a temperature condition) that leads to deterioration of the second semiconductor layer 51. Therefore, it is preferable that the first semiconductor layers 21, 31, 41 are formed before formation of the second semiconductor layer 51. For example, in the case where a low temperature polysilicon layer is used as the first semiconductor layers 21, 31, 41 and an oxide semiconductor layer is used as the second semiconductor layer 51, it is necessary to heat to about 450° C. in order to form a low temperature polysilicon layer in the semiconductor device 1. At that temperature, however, there is a possibility that an oxide semiconductor is deteriorated. To address the above, the first semiconductor layers 21, 31, 41, or a low temperature polysilicon layer, are formed before formation of the second semiconductor layer 51, or an oxide semiconductor layer.

Subsequently, on the first insulating layer 12, the first gate electrode layer 22 for covering at least a part of the first semiconductor layer 21, the first gate electrode layer 32 for covering at least a part of the first semiconductor layer 31, and the capacitor electrode layer 42 for covering at least a part of the first semiconductor layer 41 are formed. The first gate electrode layers 22, 32 and the capacitor electrode layer 42 may be formed by removing an unnecessary part from a single electrically conducting layer (for example, laminated layers of titanium and aluminum).

Then, phosphorus ions are injected into the source region 21b and the drain region 21c of the first semiconductor layer 21 to thereby achieve low resistance of the regions. By injecting phosphorus ions into end portions of the first semiconductor layer 21, or a low temperature polysilicon layer, as described above, the resistance of the first semiconductor layer 21 is made so low that allows a sufficient current to flow in the channel region 21a. Further, boron ions are injected into the source region 31b and the drain region 31c of the first semiconductor layer 31 to thereby achieve low resistance of the first semiconductor layer 31 so that a sufficient current flows in the channel region 31a. Still further, phosphorus ions are injected into the entire first semiconductor layer 41 to thereby achieve low resistance of the first semiconductor layer 41 so that the entire first semiconductor layer 41 constitutes a capacitor electrode.

Subsequently, the first upper insulating layer 13 made of a silicon nitride film etc., is formed so as to cover the upper sides of the first gate electrode layers 22, 32 and the capacitor electrode layer 42. The first upper insulating layer 13 may be formed by laminating organic insulating material, such as photosensitive acryl, etc., as a planarization layer. By laminating photosensitive acryl, as described above, it is possible to make a much smoother surface of the first upper insulating layer 13, compared to a case in which the first upper insulating layer 13 is made from only inorganic material by means of CVD (chemical vapor deposition).

Subsequently, the second semiconductor layer 51 is formed on the first insulating layer 12 (more specifically, on the first upper insulating layer 13). Then, the second insulating layer 14 made of a silicon nitride film, etc., is formed so as to cover the upper side of the second semiconductor layer 51. Further, the second gate electrode layer 52 is formed on the second insulating layer 14 so as to cover at least a part (more specifically, the channel region 51a) of the second semiconductor layer 51. In the above, the second semiconductor layer 51 may be formed, for example, by removing an unnecessary part from an oxide semiconductor layer formed in a wide area of the semiconductor device 1. Similarly, the second gate electrode layer 52 as well may be formed by removing an unnecessary part from a single electrically conducting layer (for example, laminated layers of titanium and aluminum).

Subsequently, as shown in FIG. 2B, boron ions 70, or impurities, are injected into the second semiconductor layer 51. For example, in the case where the second insulating layer 14 is formed having a thickness of 100 nm, the boron ions 70 may be injected with the acceleration energy 28 keV in a dose amount 2E14 to 1E15 cm⁻².

The boron ions 70 injected from above the semiconductor device 1 in the above described condition reaches the second semiconductor layer 51 but not the first semiconductor layers 21, 31, 41. As the upper side of the channel region 51a of the second semiconductor layer 51 is covered by the second gate electrode layer 52, the boron ions 70 do not reach the channel region 51a of the second semiconductor layer 51, as being shielded by the second gate electrode layer 52. That is, with an appropriate ion injection condition set and the second gate electrode layer 52 formed in advance, as described above, it is possible to partially destroy connection between elements in the second semiconductor layer 51 to thereby generate a defect to achieve low resistance of the source region 51b and the drain region 51c, without affecting other areas.

Subsequently, as shown in FIG. 2C, annealing process is applied to the semiconductor device 1, using a laser 80 or heat 81. For example, in the case of using an excimer laser device, the laser 80 having a wavelength of 308 nm may be irradiated with an output of 200 to 400 mJ/cm² twice per one point. In the case of using a heating device such as a furnace, etc., the heat 81 may be applied for one hour at temperature 280° C. to 350° C.

With annealing process with the laser 80 or heat 81 applied, as described above, it is possible to densify the second semiconductor layer 51 to thereby improve tolerance thereof to an etching gas. Also, with annealing process applied, the impurity, such as the boron ions 70 etc., injected in the source region 51b and the drain region 51c, invade into between elements constituting the oxide semiconductor, which causes re-aligning of the elements. With the above, the density of the second semiconductor layer 51 in the source region 51b and the drain region 51c is enhanced.

Subsequently, as shown in FIG. 2D, the second upper insulating layer 15 is formed so as to cover the upper sides of the first gate electrode layers 22, 32, the capacitor electrode layer 42, and the second gate electrode layer 52. Similar to the first upper insulating layer 13, the second upper insulating layer 15 may be made of an insulating layer, such as a silicon nitride film, etc., or by laminating the insulating layer and an organic insulating layer (planarization layer) such as acryl, etc.

Subsequently, as shown in FIG. 2D, a contact hole H1 reaching the first semiconductor layer 21, a contact hole H2 reaching the second semiconductor layer 51, a contact hole H3 reaching the first gate electrode layer 22, and a contact hole H4 reaching the second gate electrode layer 52 are opened. Specifically, the contact hole H1 extends from the upper surface of the second upper insulating layer 15 through the second insulating layer 14, the first upper insulating layer 13, and the first insulating layer 12 to reach the first semiconductor layer 21. The contact hole H2 extends through the second upper insulating layer 15 and the second insulating layer 14 to reach the second semiconductor layer 51. The contact hole H2 does not reach the first upper insulating layer 13 and the first insulating layer 12. The contact hole H3 extends through the second upper insulating layer 15, the second insulating layer 14, and the first upper insulating layer 13 to reach the first gate electrode layer 22. The contact hole H3 does not reach the first insulating layer 12. The contact hole H4 extends through the second upper insulating layer 15 to reach the second gate electrode layer 52. The contact hole H4 does not reach the second insulating layer 14, the first upper insulating layer 13, and the first insulating layer 12.

As described above, the first semiconductor layers 21, 31, 41 are formed before formation of the second semiconductor layer 51. Therefore, the second semiconductor layer 51 is formed in a layer upper than the first semiconductor layers 21, 31, 41, and the contact hole H2 extending to the second semiconductor layer 51 is formed so as to be shorter than the contact hole H1 extending to the first semiconductor layer 21, 31, 41.

In this embodiment, formation of the contact holes H1 to H4 begins concurrently through dry etching process using fluorine-based etching gas 90. As the contact hole H2 is shorter than the contact hole H1, the upper surface of the second semiconductor layer 51 is exposed to the etching gas 90 during a period from when the contact hole H2 has reached the second semiconductor layer 51 to when the contact hole H1 reaches the first semiconductor layer 21, 31, 41.

In such a situation as well, the second semiconductor layer 51 has acquired tolerance to the etching gas 90 through application of annealing process. Therefore the second semiconductor layer 51 is not etched by the etching gas, and thus it is possible to ensure reliable contact to the electrode layers 53, 54 to be formed at a subsequent step.

Subsequently, as shown in FIG. 2E, a plurality of electrode layers for electric connection to the first semiconductor layers 21, 31, 41, the first gate electrode layers 22, 32, the capacitor electrode layer 42, the second semiconductor layer 51, and the second gate electrode layer 52 are formed. More specifically, the electrode layers 23, 24 connected to the source region 21b and drain region 21c of the first semiconductor layer 21, respectively, the electrode layer 25 connected to the first gate electrode layer 22, the electrode layers 33, 34 connected to the source region 31b and drain region 31c of the first semiconductor layer 31, respectively, the electrode layer 35 connected to the first gate electrode layer 32, the electrode layer 43 connected to the first semiconductor layer 41, the electrode layer 44 connected to the capacitor electrode layer 42, the electrode layers 53, 54 connected to the source region 51b and drain region 51c of the second semiconductor layer 51, respectively, and the electrode layer 55 connected to the second gate electrode layer 52 are formed.

The respective electrode layers are formed extending from the upper surface of the second upper insulating layer 15 through any of the contact holes H1 to H4 to reach any of the first and second semiconductor layers 21, 31, 41, 51, the first and second gate electrode layers 22, 32, 52, or the capacitor electrode 42. Note that the respective electrode layers may be formed by means of photolithography technique, for example, by removing an unnecessary part on the upper side of the second upper insulating layer 15. As the second semiconductor layer 51 is present at the bottom of the contact hole H2, not being etched by the etching gas, it is possible to ensure reliable contact between the electrode layers 53, 54 and the second semiconductor layer 51 to ensure electric connection therebetween.

Note that impurities, such as phosphorus ions, not limited to the boron ions 70, may be injected into the source region 51b and the drain region 51c. Further note that laser may be irradiated to the source region 51b and the drain region 51c, using the second gate electrode layer 52 as a mask, rather than injection of impurities, such as the boron ions 70, etc. With the above as well, it is possible to generate a defect in a film in the source region 51b and drain region 51c in the second semiconductor layer 51, to thereby achieve lower resistance of the regions.

In the case of using the laser 80 in annealing process, the second upper insulating layer 15 may be formed before application of the annealing process.

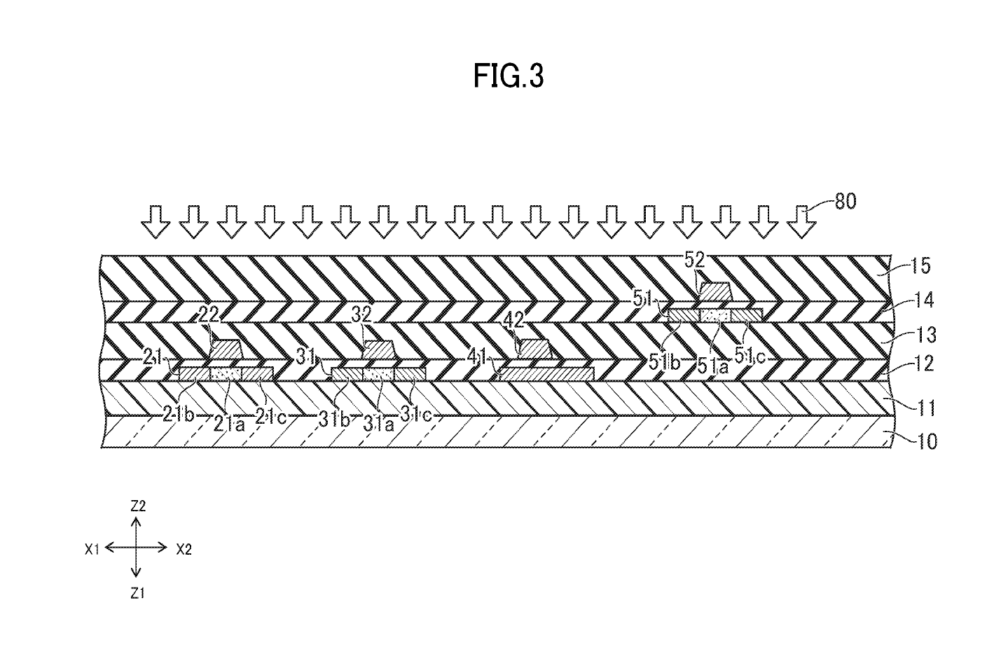

FIG. 3 shows another example of a method for manufacturing the semiconductor device 1. As shown in FIG. 3, when a laser 80 is irradiated after formation of the second upper insulating layer 15, it is possible to densify the source region 51b and drain region 51c of the second semiconductor layer 51 and to improve tolerance to the fluorine-based etching gas. In this case, it is preferable that the second upper insulating layer 15 is formed so as to have light transmitting property.

### 3. Modified Example

The present invention is not limited to the above described embodiment, and various modifications may be made. In the following, an example (a modified example) of another embodiment for rendering the present invention into practice will be described.

### 3-1. First Modified Example

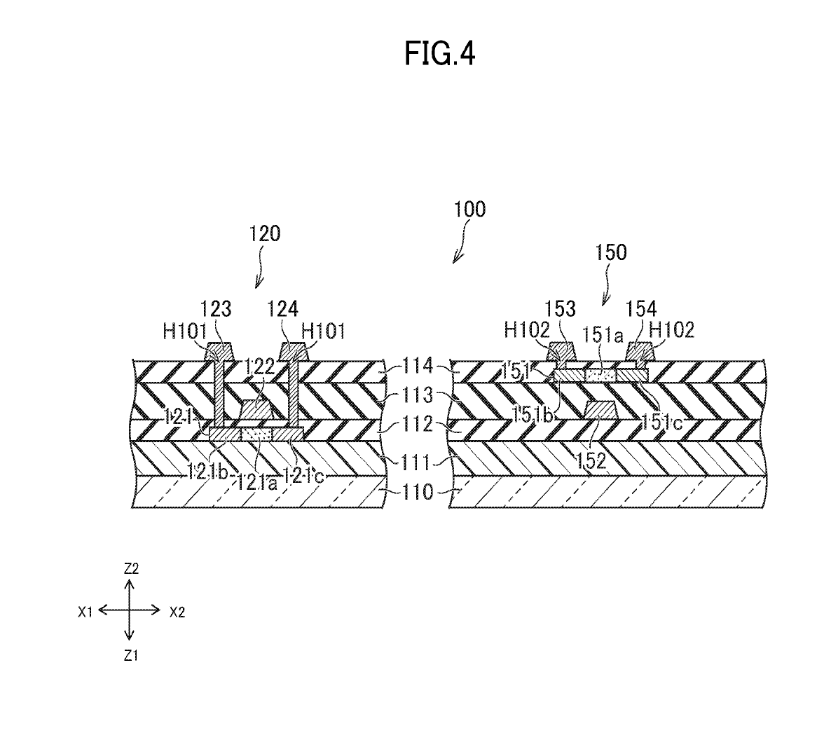

In the following, a first modified example will be described referring to FIG. 4. FIG. 4 is a schematic cross sectional view showing a part of a semiconductor device 100 according to the first modified example. In FIG. 4, an N-type transistor 120 and an oxide transistor 150 are shown in particular.

As shown in FIG. 4, the N-type transistor 120 is a top gate type, and includes a first gate electrode layer 122 made from predetermined electrically conducting material formed on a first semiconductor layer 121 such as a low temperature polysilicon layer, etc. Meanwhile, the oxide transistor 150 is a bottom gate type, and a second gate electrode layer 152 made from predetermined electrically conducting material is formed below a second semiconductor layer 151 made of an oxide semiconductor layer, etc. Specifically, the second gate electrode layer 152 is covered by at least a part of the second semiconductor layer 151 below the second semiconductor layer 151. That is, the second gate electrode layer 152 overlaps the second semiconductor layer 151 in the vertical direction (the Z axial direction).

The upper side of the second gate electrode layer 152 is covered by a first upper insulating layer 113 made of a silicon nitride film, etc., and the second semiconductor layer 151 is formed on the first upper insulating layer 113. The upper side of the second semiconductor layer 151 is covered by a second insulating layer 114 made of a silicon nitride film, etc.

In this modified example, the second gate electrode layer 152 is formed in the same layer as the first gate electrode layer 122 that constitutes the N-type transistor 120. More specifically, in the semiconductor device 100, a substrate 110 made of an insulating substrate, an undercoat layer 111, such as a silicon oxide film or a silicon nitride film, etc., and a first insulating layer 112, such as a silicon oxide film, etc., are laminated, and the first gate electrode layer 122 and the second gate electrode layer 152 are formed on the first insulating layer 112. As the first gate electrode layer 122 and the second gate electrode layer 152 are formed in the same layer, as described above, it is possible to form both of the first gate electrode layer 122 and the second gate electrode layer 152 through one application of a masking process and etching process according to a photolithography technique. Therefore, it is possible to reduce the number of times of application of that process. Further, by covering both of the first and second gate electrode layers 122, 152 by one insulating layer (the first upper insulating layer 113 here), it is possible to reduce the number of insulating layers formed in the semiconductor device 100, and therefore to simplify manufacturing of the semiconductor device 100. This can make thinner the thickness of the semiconductor device 100 in the vertical direction (the Z axial direction). As the first upper insulating layer 113 is a planarization film on the gate electrode layer 152 of the N-type transistor 120 and also a gate insulating film of the oxide transistor 150, the first upper insulating layer 113 may be made from inorganic material, such as a silicon oxide film or a silicon nitride film, etc.

In the semiconductor device 100, electrode layers 123, 124 connected to the source region 121b and drain region 121c of the first semiconductor layer 121, respectively, and electrode layers 153, 154 connected to the source region 151b and drain region 151c of the second semiconductor layer 151, respectively, are formed. If the second semiconductor layer 151 is placed in such environment that satisfies a condition (for example, a temperature condition) for forming the first semiconductor layer 121, it is possible that the second semiconductor layer 151 is deteriorated. Therefore, the second semiconductor layer 151 is formed in a layer positioned upper than the first semiconductor layer 121. Thus, the first contact hole H101 through which the electrode layer 123, 124 extends is formed longer in the vertical direction (deeper) than a second contact hole H102 through which the electrode layer 153, 154 extends. More specifically, the first contact hole H101 is opened in three layers including the second insulating layer 114, the first upper insulating layer 113, and the first insulating layer 112, and the second contact hole H202 is opened in one layer, namely, the second insulating layer 114.

In concurrent formation of the first and second contact holes H101, H102, the second contact hole H102 for exposing the upper surface of the second semiconductor layer 151 is formed before the first contact hole H101 reaches the upper surface of the first semiconductor layer 121. Therefore, the second semiconductor layer 151 remains exposed to an etching gas during a period from when the second contact hole H102 has been formed to when the first contact hole H101 is formed.

In view of the above, as described in this embodiment, heat or light annealing process is applied before formation of the first and second contact holes H101, H102 to thereby densify the second semiconductor layer 151 to improve tolerance thereof to an etching gas. Also, with ion injection into the source and drain regions 151b, 151b of the second semiconductor layer 151 and subsequent annealing process, the regions with the ions injected therein are densified so as to have a higher density than that of other regions. With the above, it is possible to prevent the second semiconductor layer 151 from being etched by an etching gas and to ensure reliable contact between the second semiconductor layer 151 and the electrode layers 153, 154.

### 3-2. Second Modified Example

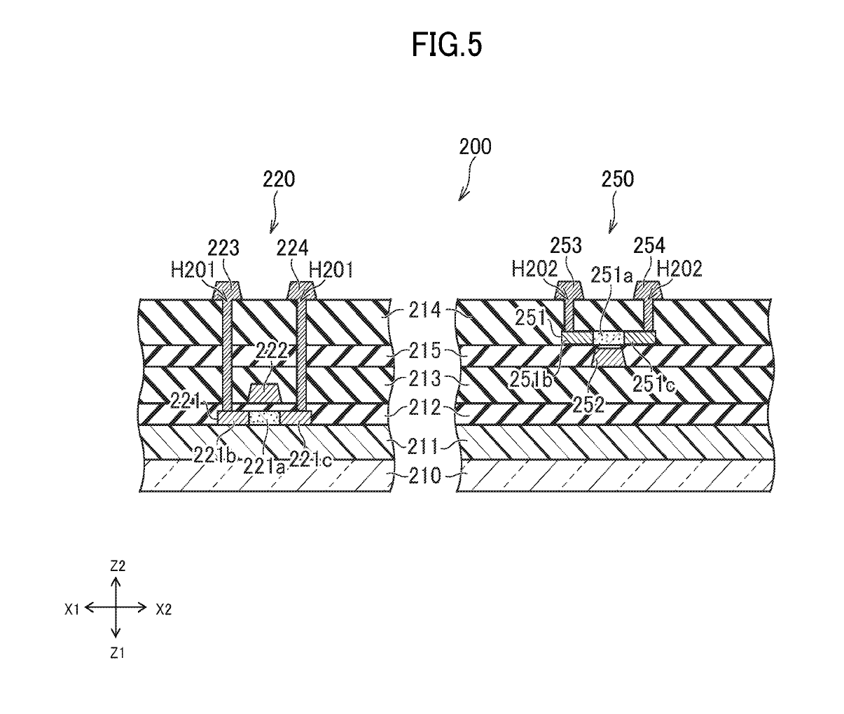

In the following, a second modified example will be described referring to FIG. 5. FIG. 5 is a schematic cross sectional view showing apart of a semiconductor device 200 according to the second modified example, and shows, in particular, an N-type transistor 220 and an oxide transistor 250, similar to FIG. 3.

In the case where the N-type transistor 220 is a top gate type and the oxide transistor 250 is a bottom gate type, a first gate electrode layer 222 constituting the N-type transistor 220 and a second gate electrode layer 252 constituting the oxide transistor 250 may not be necessarily formed in the same layer. For example, as shown in FIG. 5, the second gate electrode layer 252 may be formed on a first upper insulating layer 213, or an insulating layer covering the upper side of the first gate electrode layer 222. In this modified example, similar to the above described embodiment, the first gate electrode layer 222 is formed on a first insulating layer 212 covering the upper side of a first semiconductor layer 221. Also, the first semiconductor layer 221 is formed on an undercoat layer 211 covering a substrate 210.

In this modified example as well, a second semiconductor layer 251, such as an oxide semiconductor layer, etc., that constitutes the oxide transistor 250, is formed in a layer upper than the first semiconductor layer 221, or a low temperature polysilicon layer that constitutes the N-type transistor 220, due to a difference in condition for formation (for example, a temperature condition). Therefore, the first contact hole H201 for exposing the upper surface of the first semiconductor layer 221 is formed longer (deeper) than the second contact hole for exposing the upper surface of the second semiconductor layer 251. In this modified example, the first contact hole H201 is opened in four layers, including a second insulating layer 214 covering the upper side of the second semiconductor layer 251, an insulating layer 215 covering the upper side of the second gate electrode layer 252, the first upper insulating layer 213, and the first insulating layer 212, while the second contact hole H202 is opened in one layer, namely, the second insulating layer 214.

In concurrent formation of the first and second contact holes H201, H202, the second semiconductor layer 251 is temporarily exposed to an etching gas. However, by applying laser or heat annealing process to the semiconductor device 200 before formation of the first and second contact holes H101, H102, it is possible to improve tolerance of the second semiconductor layer 251 to an etching gas. That is, with the above described arrangement for preventing the second semiconductor layer 251 from being etched by an etching gas, it is possible to ensure reliable contact between the second semiconductor layer 251 and the electrode layers 253, 254.

### 3-3. Third Modified Example

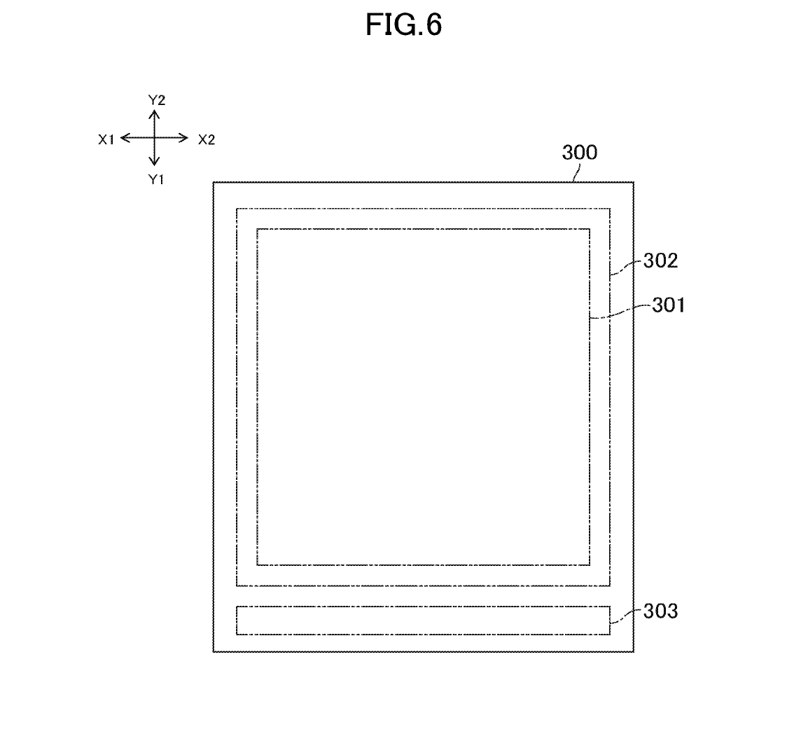

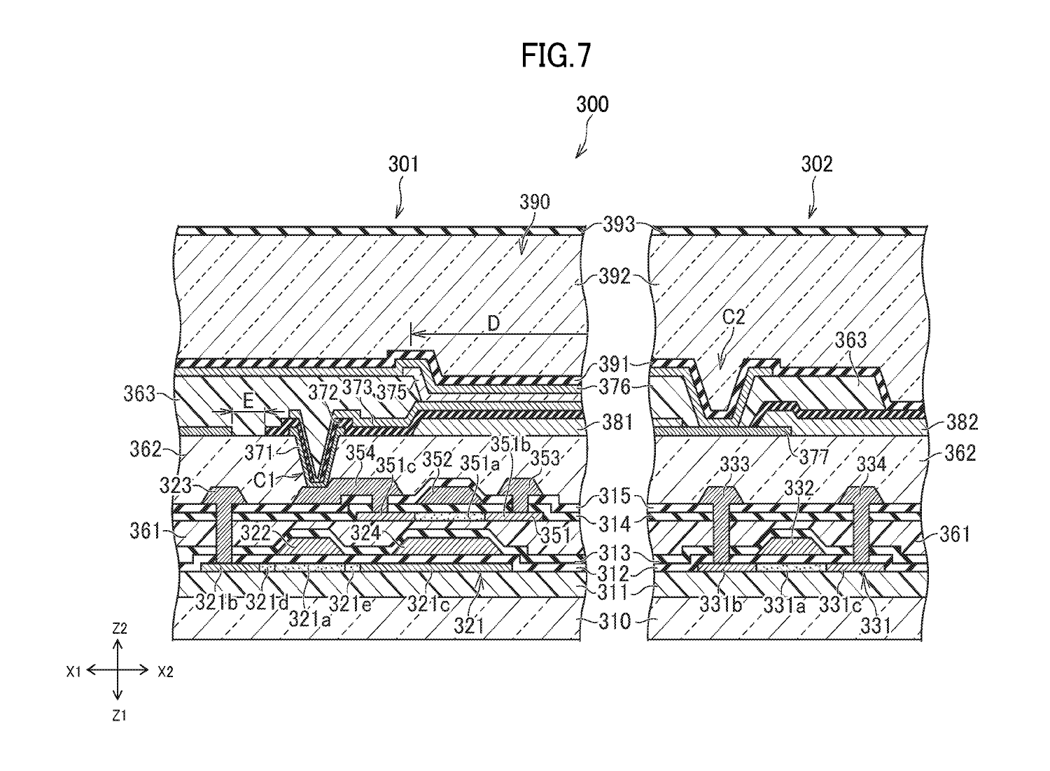

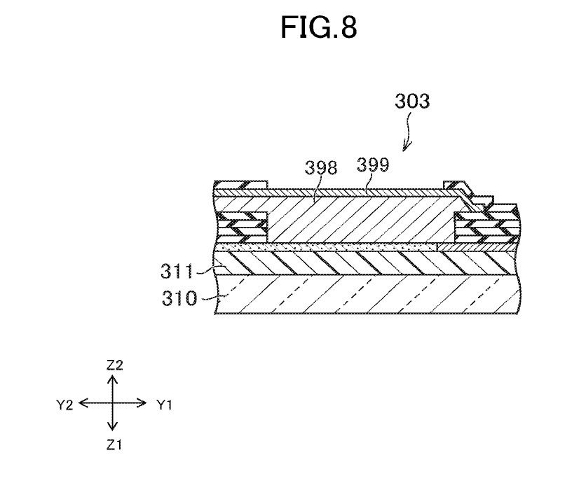

Below, a third modified example will be described referring to FIGS. 6 to 8. FIG. 6 is a schematic plan view of a display device 300 according to this modified example. FIGS. 7 and 8 are cross sectional views showing a part of the display device 300 according to this modified example.

As shown in FIG. 6, the display device 300 includes a display area 301 that is an area for emitting light of pixels constituting an image, a frame area 302 that is an area around the display area 301, a connection area 303 that is an area connected to a relay substrate such as an FPC (flexible printed circuit) (not shown), etc.

As shown in FIG. 7, a first semiconductor layer 321 and a first gate electrode layer 322 constituting an N-type transistor are formed in the display area 301, and a second semiconductor layer 351 and a second gate electrode layer 352 constituting an oxide transistor are arranged in a layer upper than the first semiconductor layer 321 and the first gate electrode layer 322. Also, a first semiconductor layer 331 and a first gate electrode layer 332 constituting a P-type transistor are formed in the frame area 302. The first semiconductor layers 321, 331 are arranged on the undercoat layer 311 formed on a substrate 310. In the frame area 302 shown in FIG. 7, an N-type transistor (not shown) may be formed in addition to a P-type transistor.

The substrate 10 is made from flexible resin material. The substrate 10 may be formed using polyimide, for example. The undercoat layer 311 is formed by laminating a silicon oxide film, a silicon nitride film, and a silicon oxide film. The silicon oxide film constituting the lowest layer of the undercoat layer 311 is available to ensure adhesion to the substrate 10. The silicon nitride film constituting the middle layer of the undercoat layer 311 is available to prevent invention of water and impurities from the outside. The silicon oxide film constituting the uppermost layer of the undercoat layer 311 is available to prevent diffusion of hydrogen atoms in the silicon nitride film into the first semiconductor layers 321, 331. Note that the undercoat layer 311 is not limited to the above described, and may be formed using one, two, four, or more layers.

Each of the first semiconductor layers 321, 331 is made of a low temperature polysilicon layer, for example. In particular, in the first semiconductor layer 321 that functions as an N-type semiconductor layer, lightly doped drain regions (LDD (lightly doped drain) region) 321d, 321e, or regions where a smaller amount of phosphorus ions are injected, are formed besides the channel region 321a, the source region 321b, and the drain region 321c. The lightly doped drain region 321d is formed between the channel region 321a and the source region 321b, while the lightly doped drain region 321e is formed between the channel region 321a and the drain region 321c. With the lightly doped drain regions 321d, 321e formed, as described above, it is possible to prevent generation of a leak current.

The upper sides of the first semiconductor layers 321, 331 are covered by a first insulating layer 312 made of a silicon oxide film. In the display area 301, the first gate electrode layer 322 and a capacitor electrode layer 324 are formed on the first insulating layer 312. The first gate electrode layer 322, the capacitor electrode layer 324, and the first semiconductor layer 321 constitute an N-type transistor. Meanwhile, in the frame area 302, the first gate electrode layer 332 that constitutes a P-type transistor, together with the first semiconductor layer 331, is formed on the first insulating layer 312.

Each of the first gate electrode layers 322, 332 is formed by laminating respective layers of titanium and aluminum. The capacitor electrode layer 324 is made from the material same as that of the first gate electrode layers 322, 332, and constitutes a holding capacitor between itself and the first semiconductor layer 321 (more specifically, the drain region 321c) that overlaps the capacitor electrode layer 324 in the vertical direction (the Z axial direction).

The upper sides of the first gate electrode layers 322, 332 are covered by the first upper insulating layer 313 made of a silicon nitride film. In the upper layer of the first upper insulating layer 313, a first planarization layer 361 made from insulating material, such as acryl, etc., is formed.

In the display area 301, the second semiconductor layer 351 is formed on the first planarization layer 361. The second semiconductor layer 351 is a layer made from oxide semiconductor, for example, of which condition (for example, a temperature condition) for formation is different from that of the first semiconductor layers 321, 331. The second semiconductor layer 351 is formed including a channel region 351a, and a source region 351b and a drain region 351c where boron ions are injected.

The upper side of the second semiconductor layer 351 is covered by a second insulating layer 314 made of a silicon nitride film, and the second gate electrode layer 352 is formed on the second insulating layer 314. Similar to the first gate electrode layer 322, the second gate electrode layer 352 may be formed by laminating respective layers of titanium and aluminum. The second gate electrode layer 352 includes a second upper insulating layer 315 made of a silicon nitride film.

A plurality of electrode layers are connected to the first semiconductor layers 321, 331 and the second semiconductor layer 351. More specifically, an electrode layer 323 connected to the source region 321b of the first semiconductor layer 321, an electrode layer 353 connected to the source region 351b of the second semiconductor layer 351, an electrode layer 354 connected to the drain region 351c of the second semiconductor layer 351, an electrode layer 333 connected to the source region 331b of the first semiconductor layer 331, and an electrode layer 334 in contact with the drain region 331c of the first semiconductor layer 331 are formed.

Each of the electrode layers is formed by laminating three layers of titanium, aluminum, and titanium, respectively. Each electrode layer protrudes above the second upper insulating layer 315. In the display area 301, the electrode layer 323 extends from above the second upper insulating layer 315 to the upper surface of the first semiconductor layer 321. The electrode layers 353, 354 extend from above the second upper insulating layer 315 to the upper surface of the second semiconductor layer 351.

A second planarization layer 362 is formed on the second upper insulating layer 315 and the respective electrode layers. The second planarization layer 362 is made from organic insulating material, such as photosensitive acryl, etc., for example. Wiring layers 381, 382 are formed on the second planarization layer 362. Each of the wiring layers 381, 382 is formed by laminating three layers of molybdenum (Mo), aluminum, and molybdenum, respectively, and used as a wiring and in formation of a capacitor additionally provided in a pixel.

In the display area 301, a pixel contact portion C1, or a hollow portion in a tapered shape resulting by so removing the second planarization layer 362, is formed. The surface of the pixel contact portion C1 is covered by a protection electrode layer 371 made from electrically conducting material such as indium tin oxide (ITO), etc. The protection electrode layer 371 is formed at a position apart from the wiring layer 381 in the left-right direction, and not electrically connected to the wiring layer 381. The protection electrode layer 371 is available to protect the electrode layer 354 that is exposed in the pixel contact portion Cl in formation of the wiring layer 381.

The upper sides of the wiring layers 381, 382 and the protection electrode layer 371 are covered by an inter-electrode insulating layer 372 made of a silicon nitride film, and a pixel electrode layer 373 is formed on the upper side of the inter-electrode insulating layer 372. The pixel electrode layer 373 is formed as a reflection electrode by laminating three layers made from indium tin oxide (ITO), argentum (Ag), and indium tin oxide, respectively. The protection electrode layer 371 is partially removed on the pixel contact portion C1 (more specifically, a part constituting a bottom surface of the tapered shape). The pixel electrode layer 373 is in contact with the protection electrode layer 371 at a position where the protection electrode layer 371 is removed, and is electrically connected to the electrode layer 354. In the display area 301, the pixel electrode layer 373, the inter-electrode insulating layer 372, and the wiring layer 381 together constitute an additional capacitor.

The protection electrode layer 371 is temporarily exposed to an etching gas used in formation of the pixel electrode layer 373 (an etching process). Therefore, heat or light annealing process may be applied to the protection electrode layer 371 before formation of the pixel electrode layer 373 so that the protection electrode layer 371 can acquire tolerance to the etching gas.

A bank layer 363, or an insulating layer constituting a partition of the display area D, is formed on the inter-electrode insulating layer 372 and the pixel electrode layer 373. The bank layer 363 is made from photosensitive acryl, similar to the second planarization layer 362. The bank layer 363 has an opening formed in the pixel region D so as to expose the surface of the pixel electrode layer 373. It is preferable that an end portion of the bank layer 363 is formed moderately inclined. This can facilitate formation of an organic layer 375 to be described later.

The bank layer 363 is in contact with the second planarization layer 362 via an opening E formed in the inter-electrode insulating layer 372. With the opening E formed, as described above, it is possible to draw water or gas generated in the second planarization layer 362 at a subsequent step of heating through the bank layer 363.

The organic layer 375 is formed on an end portion of the bank layer 363 and the pixel electrode layer 373. The organic layer 375 is formed by laminating a hole transport layer, a light emitting layer, and an electron transport layer. These layers may be formed by means of deposition such as CVD, etc., or by applying onto solvent. As electric power flows from the pixel electrode layer 373 to an opposed electrode layer 376 to be described later, light is emitted from a part of the light emitting layer where the electric power flows.

Note that the organic layer 375 may be formed as a sub-pixel for emitting light in respective colors, namely, red, green, and blue, in the pixel region D, or formed over the entire display area 301 (solid state). When the organic layer 375 is formed solid, a color film (not shown) may be formed on the organic layer 375 so that a wavelength for a desired color is extracted. Alternatively, a light emitting layer may be arranged in the pixel region D, and a hole transport layer and an electron transport layer may be arranged over the entire display area 301.

An opposed electrode layer 376 is formed on the bank layer 363 and the organic layer 375. The opposed electrode layer 376 is formed over the entire display area 301. When the display device 300 employs a top emission structure, the opposed electrode layer 376 needs to have light transmitting property. The opposed electrode layer 376 is formed by applying magnesium-argentum (MgAg), for example, so as to form a thin film having such a thickness that allows light transmission.

In the frame area 302, an electrically conducting layer 377 made from predetermined electrically conducting material is formed on the second planarization layer 362, and a peripheral contact portion C2, or a tapered hollow portion formed by so hollowing out the bank layer 363, is formed at a position where the electrically conducting layer 377 is formed in the left-right direction (the X axial direction) and the front-back direction (the Y axial direction). The opposed electrode layer 376 is in contact with the electrically conducting layer 377 through the peripheral contact portion C2, and electrically connected to the electrically conducting layer 377. With the above, it is possible to draw electricity in the opposed electrode layer 376 and to prevent increase of electric resistance.

A sealing layer 390 having a structure in which a silicon nitride film 391, an organic resin layer 392, and a silicon nitride film 393 are laminated is formed on the opposed electrode layer 376. The sealing layer 390 prevents invasion of water from outside into the organic layer 375. Note that a touch panel (not shown) and a protection film may be arranged on the sealing layer 390.

As shown in FIG. 8, a routing wiring layer 398 and a terminal layer 399 are formed in the connection area 303. The routing wiring layer 398 is formed by laminating three layers of titanium, aluminum, and titanium, respectively, and connected to the respective electrode layers (for example, any of the electrode layers 323, 333, 334, 353, 354) connected to the first semiconductor layers 321, 331 or the second semiconductor layer 351. The terminal layer 399 is formed on the routing wiring layer 398. The terminal layer 399 is made from predetermined metal material, and connected to the electrically conducting layer 377 formed in the frame area 302. With the above, the electrode layers 323, 333, 334, 353, 354 and the electrically conducting layer 377 can be electrically connected to a wiring mounted on a relay substrate via the routing wiring layer 398 and the terminal layer 399.

As shown in FIG. 7, the second semiconductor layer 351 mounted on the display device 300 is formed at a position higher than the first semiconductor layers 321, 331 as a condition (for example, a temperature condition) for formation of the second semiconductor layer 351 is different from that of the first semiconductor layers 321, 331. Here, in formation of the respective electrode layers in contact with the first and second semiconductor layers, contact holes for exposing the surfaces of the first and second respective semiconductor layers are formed. As the second semiconductor layer 351 is formed at a position higher than the first semiconductor layers 321, 331, the second semiconductor layer 351 is temporarily exposed to an etching gas.

In view of the above, by applying heat or light annealing process to the second semiconductor layer 351 before formation of the contact hole, as described in this embodiment, it is possible to improve tolerance of the second semiconductor layer 351 to an etching gas. With the above, it is possible to ensure reliable contact between the second semiconductor layer 351 and the electrode layers 353, 354. As described above, a method for manufacturing a semiconductor device described in this embodiment can be applied to various devices such as a display device.

What is claimed is:

1. A method for manufacturing a semiconductor device, comprising steps of:
forming a first semiconductor layer on an insulating surface;
forming a first insulating layer covering an upper side of the first semiconductor layer;
forming a second semiconductor layer on the first insulating layer;
forming a second insulating layer covering an upper side of the second semiconductor layer;
opening a first contact hole extending through the first insulating layer and the second insulating layer to reach the first semiconductor layer, and a second contact hole extending through the second insulating layer to reach the second semiconductor layer but not reaching the first insulating layer; and
executing annealing process using laser or heat,
wherein the annealing process is executed after the step of forming the second insulating layer before the step of opening the first contact hole and the second contact hole.

2. The method for manufacturing a semiconductor device according to claim 1, further comprising steps of:
forming a first gate electrode layer covering at least a part of the first semiconductor layer on the first insulating layer; and
forming a first upper insulating layer covering an upper side of the first gate electrode layer,
wherein the second semiconductor layer and the second insulating layer are formed on the first upper insulating layer,
the first contact hole is opened so as to further extend through the first upper insulating layer, and
the second contact hole does not reach the first upper insulating layer.

3. The method for manufacturing a semiconductor device according to claim 2, further comprising steps of:
forming a second gate electrode layer covering at least a part of the second semiconductor layer on the second insulating layer; and
forming a second upper insulating layer covering upper sides of the first gate electrode layer and the second gate electrode layer,
wherein the first contact hole and the second contact hole further extend through the second upper insulating layer.

4. The method for manufacturing a semiconductor device according to claim 2, further comprising a step of
forming a second gate electrode layer covered by at least a part of the second semiconductor layer below the second semiconductor layer.

5. The method for manufacturing a semiconductor device according to claim 4, wherein
the first gate electrode layer and the second gate electrode layer are formed on the first insulating layer, and
the first upper insulating layer covers upper sides of the first gate electrode layer and the second gate electrode layer.

6. The method for manufacturing a semiconductor device according to claim 1, further comprising a step of
an ion injecting process injecting ions into the second semiconductor layer,
wherein the ion injecting process is executed after the step of forming the second insulating layer before the step of executing the annealing process.

7. The method for manufacturing a semiconductor device according to claim 3, further comprising a step of
an impurity injecting process injecting impurities into a part of the second semiconductor not covered by the second gate electrode layer,
wherein the impurity injecting process is executed after the step of forming the second insulating layer before the step of executing the annealing process.

8. The method for manufacturing a semiconductor device according to claim 3, further comprising a step of
an irradiating process irradiating a laser to a part of the second semiconductor not covered by the second gate electrode layer,
wherein the irradiating process is executed after the step of forming the second insulating layer before the step of executing the annealing process.

9. The method for manufacturing a semiconductor device according to claim 1, wherein
the first semiconductor layer includes any of single-crystalline silicon, poly-crystalline silicon, and microcrystal silicon, and
the second semiconductor layer includes oxide semiconductor.

10. The method for manufacturing a semiconductor device according to claim 1, further comprising a step of
forming electrode layers for electrically connecting to the first semiconductor layer and the second semiconductor layer respectively,
wherein the forming the electrode layers is executed after the step of opening the first contact hole and the second contact hole.
